(19) United States
(12) Patent Application Publication
(10) Pub. No.: US 2026/0043844 A1
(43) Pub. Date: Feb. 12, 2026

(54) TEMPERATURE CONTROLLED TEST SYSTEM AND MANIFOLD THEREOF, METHOD OF DISTRIBUTING WORKING FLUID USING MANIFOLD, AND TESTED DEVICE UNDER TEST AND METHOD OF PRODUCING THE SAME

(71) Applicant: MPI CORPORATION, Zhubei City (TW)

(72) Inventor: CHUN-KAI HSIEH, Zhubei City (TW)

(21) Appl. No.: 19/203,465

(22) Filed: May 9, 2025

Related U.S. Application Data
(60) Provisional application No. 63/679,822, filed on Aug. 6, 2024.

(51) Int. Cl. G01R 31/28

(52) U.S. Cl. CPC G01R 31/2875

(57) ABSTRACT

A temperature controlled test system, a manifold and a method of distributing working fluid using the manifold. A temperature controlled test system includes a working fluid supply machine to supply a working fluid, an output tube connected to the working fluid supply machine to receive the working fluid, a temperature control head connected to the output tube, and a manifold, and a plurality of testing caps. The manifold includes a single thermal air inlet that is connected to the temperature control head, a plurality of nozzles, and a distributing mechanism that is configured to distribute the working fluid to at least two nozzles. The testing caps are respectively connected to the nozzles.

### CROSS-REFERENCE TO RELATED PATENT APPLICATION

This application claims the benefit of priority to the U.S. Provisional Patent Application Ser. No. 63/679,822, filed on Aug. 6, 2024, which application is incorporated herein by reference in its entirety.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a temperature controlled test system, a manifold thereof and method of distributing a working fluid using the same, and more particularly to an electrical testing equipment for testing devices.

### BACKGROUND OF THE DISCLOSURE

The present disclosure relates generally to the field of electrical testing equipment for testing devices, such as semiconductors. A device-under-test (DUT) is a manufactured product undergoing testing. Control of a temperature of the DUT (device-under-test) in the electrical testing equipment has been practiced for a period of time. These types of devices are often tested at a particular temperature, so as to simulate possible ambient temperatures during normal use.

The electrical testing equipment includes a temperature controlled system and a testing system. The temperature controlled system includes a thermal test head suspended by a support arm that receives a temperature controlled air flow through an output tube from an air supply system. The thermal test head is configured to have a single chamber or cap that is designed to accommodate one or more DUTs, ensuring control and maintenance of a precise temperature within the chamber or cap. This arrangement ensures effective temperature management of the DUTs in a confined environment.

Testing multiple DUTs at the same environmental temperature in an individual manner requires separate tests, leading to low testing efficiency and high setup costs for multiple testing environments.

Furthermore, placing multiple DUTs in the single chamber or cap of the thermal test head at the same environmental temperature may cause mutual interference among the DUTs. For example, multiple DUTs in close proximity can generate electromagnetic signals or noise that interfere with each other, potentially affecting the accuracy of the tests, particularly if the DUTs are sensitive to electrical signals. Additionally, the DUTs may obstruct airflow, which degrade the performance of thermal testing. In particular, obstruction of airflow may lead to uneven or inaccurate temperature control, resulting in temperature distribution non-uniformity and reduced test accuracy.

### SUMMARY OF THE DISCLOSURE

In response to the above-referenced technical inadequacies, the present disclosure provides a manifold designed to distribute a single thermal air inlet into multiple nozzles, thereby ensuring that a working fluid output from each nozzle is at the same temperature.

In order to solve the above-mentioned problems, one of the technical aspects adopted by the present disclosure is to provide a manifold of a temperature controlled test system for conditioning a device-under-test. The manifold includes a single thermal air inlet for receiving a working fluid, a plurality of nozzles, a distributing mechanism that is fluidly communicated with the single thermal air inlet to the plurality of nozzles and is configured to distribute the working fluid to at least two of the nozzles, and a flow path defined in the manifold. The flow path is substantially structurally symmetrical between the nozzles along a central axis of the single thermal air inlet. Each of the nozzles has a flow path length along the flow path that is substantially identical, and has a cross-sectional area in the flow path that is substantially identical, so that the working fluid output from each of the nozzles has a substantially uniform flow rate, a substantially uniform temperature, or both.

In order to solve the above-mentioned problems, another one of the technical aspects adopted by the present disclosure is to provide a temperature controlled test system, which includes a working fluid supply machine to supply a working fluid, an output tube connected to the working fluid supply machine to receive the working fluid, a temperature control head connected to the output tube, the above-mentioned manifold, and a plurality of testing caps respectively connected to the plurality of nozzles. The single thermal air inlet is connected to the temperature control head.

In order to solve the above-mentioned problems, yet another one of the technical aspects adopted by the present disclosure is to provide a method of distributing a working fluid from a temperature controlled test system to a plurality of testing caps. The method includes the processes of: providing a single thermal air inlet for receiving the working fluid; providing a distributing mechanism to connect with the single thermal air inlet to distributing the working fluid to a plurality of fluid test flows; providing a plurality of nozzles to connect with the distributing mechanism and respectively receive the fluid test flows; and arranging a flow path of the working fluid that is substantially structurally symmetrical between the nozzles along a central axis of the single thermal air inlet. Each of the nozzles has a flow path length along the flow path that is substantially identical, and a cross-sectional area in the flow path that is substantially identical so that the working fluid output from each of the nozzles has a substantially uniform flow rate, a substantially uniform temperature, or both.

Therefore, in the manifold provided by the present disclosure, by virtue of a structurally symmetrical flow path design between different nozzles, the flow paths can be ensured that are substantially identical. As a result, the flow rate and the temperature of the working fluid from each nozzle are effectively the same. More specifically, the substantially identical flow path length of each nozzle along the flow path ensures that the working fluid travels an equal distance through every nozzle, preventing any discrepancies in fluid delivery caused by length variations. Additionally, the substantially identical cross-sectional area within the flow path ensures that the fluid flows through each nozzle at the same rate, providing a uniform output across all nozzles. As a result, the working fluid exiting from each nozzle is uniform in both flow rate and temperature, effectively preventing any imbalances in the thermal environment. This uniformity is particularly beneficial for conditioning the device-under-test (DUT), as it ensures that each DUT is exposed to identical thermal conditions, thereby enhancing the accuracy and reliability of the testing. In essence, the symmetrical design of the manifold in the flow path ensures even distribution of temperature-controlled air or fluid to each nozzle, eliminating issues such as uneven temperature gradients or fluctuating flow rates that could otherwise compromise the testing process.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic side view of a temperature controlled system according to a first embodiment of the present disclosure;

FIG. 2 is a partially-enlarged perspective view of a manifold connected between a temperature control head and two caps according to the first embodiment of the present disclosure;

FIG. 3 is an exploded perspective view of FIG. 2;

FIG. 4 is an enlarged perspective view of the manifold according to the present disclosure;

FIG. 5 is another perspective view of the manifold according to the present disclosure;

FIG. 6 is a cross-sectional perspective view taken along line VI-VI of FIG. 4;

FIG. 7 is a schematic enlarged view of part VII of FIG. 6.

FIG. 8 is a cross-sectional planar view of FIG. 6;

FIG. 9 is a cross-sectional planar view taken along line XI-XI of FIG. 4;

FIG. 10 is a perspective view of the manifold according to a second embodiment of the present disclosure;

FIG. 11 is a flow chart of a method of distributing a working fluid using the manifold according to the present disclosure; and

FIG. 12 is a schematic view of a testing assembly connected with an unpackaged semiconductor device according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

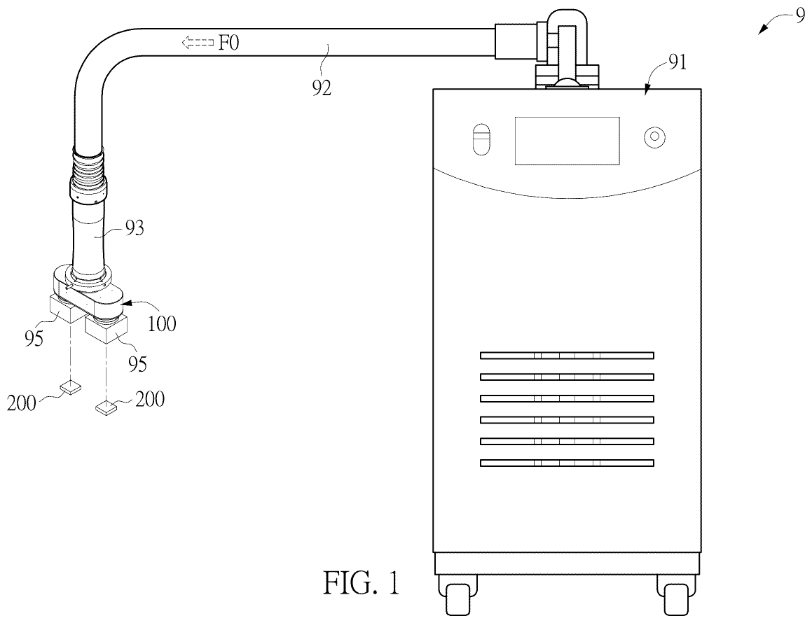

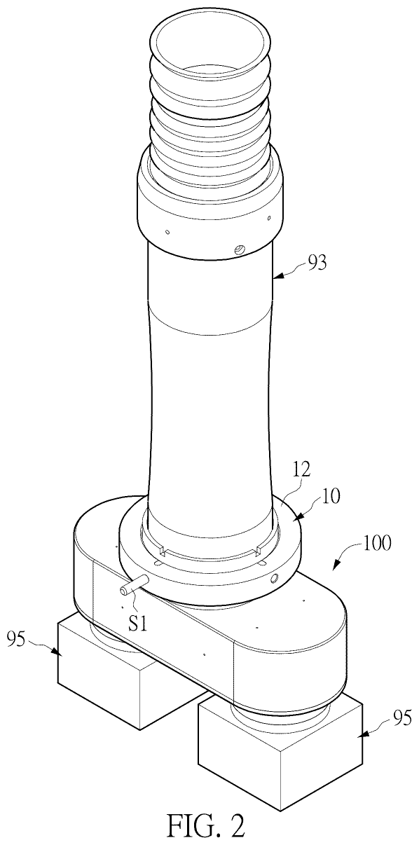

Referring to FIG. 1 to FIG. 3, the present disclosure provides a temperature controlled test system 9 for testing an object to be measured that is a device-under-test (DUT) 200.

The temperature controlled test system 9 is an essential tool for semiconductor integrated circuit (IC) testing, and provides precise and customized temperature control for testing devices (such as microprocessors, a memory, and mixed-signal ICs). For example, the temperature controlled test system 9 can replicate temperature variations in a laboratory environment, thereby allowing engineers to conduct tests under a desired set of temperature conditions, to accurately simulate real-world temperature environments, and to predict device behavior and reliability.

The electric device-under-test (DUT) 200 undergoing the temperature controlled test system 9 can be, for example, a semiconductor device, a microprocessor, a memory, mixed-signal IC, a printed circuit board (PCB), an electronic device, and anon-electronic assembly . . . etc.

The temperature controlled test system 9 includes a working fluid supply machine 91, an output tube 92, a temperature control head 93, a manifold 100, and at least two testing caps 95. The working fluid supply machine 91 is a working fluid input source that generates and outputs a working fluid F0. The working fluid F0 can be a compressed air flow. The output tube 92 can be a flexible hose. The output tube 92 is connected to the working fluid supply machine 91 for receiving the working fluid F0.

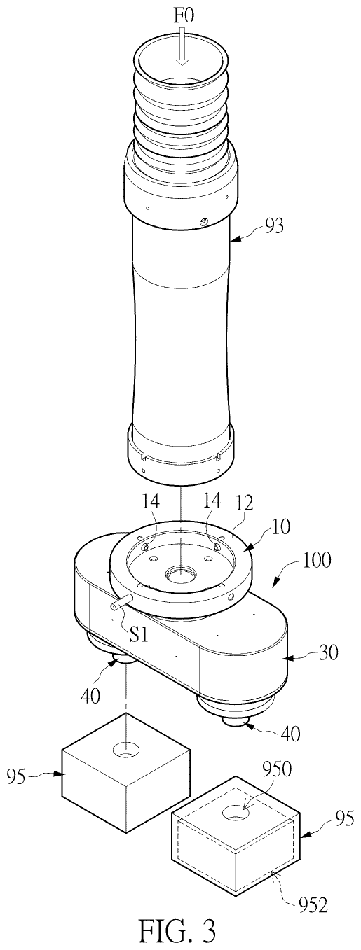

As shown in FIG. 3, the temperature control head 93, the manifold 100, and the at least two testing caps 95 are combined to form a temperature controlled test module. The manifold 100 is connected between the temperature control head 93 and the two testing caps 95. The temperature controlled test module is used to receive the working fluid F0 from the working fluid supply machine 91, and can change a temperature of the working fluid F0 to a preset temperature for a testing condition in the testing caps 95. Specifically, the original working fluid F0 usually has a temperature lower than the preset temperature. The temperature control head 93 is connected to the output tube 92 for receiving the working fluid F0, and is configured to heat the working fluid F0 to the preset temperature for achieving a precise temperature control. In a practical embodiment of the present disclosure, the temperature control head 93 is a heater. The temperature of the working fluid F0 provided from the working fluid supply machine 91 is lower than, or equal to a room temperature. For example, a temperature range of the working fluid F0 is from −100 degrees centigrade to the room temperature. Through the temperature control head 93, the working fluid F0 can be heated to, for example, −80 to 225 degrees centigrade, and then is provided to the testing caps 95 through the manifold 100.

As shown in FIG. 3, each testing cap 95 includes a working fluid inlet 950 and a cavity 952 for accommodating the DUT 200 (as shown in FIG. 1). The working fluid inlet 950 is connected to a nozzle 40 of the manifold 100 and extends into the cavity 952.

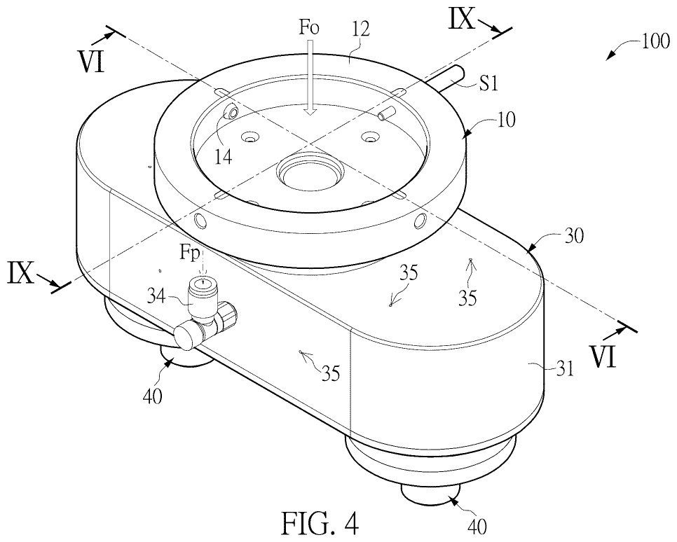

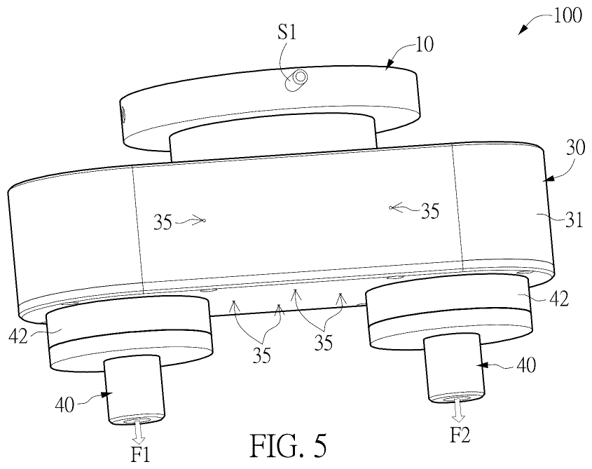

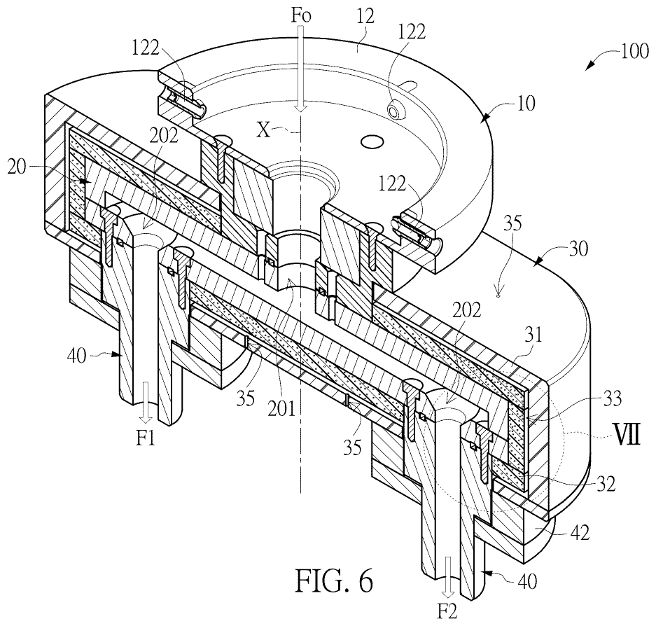

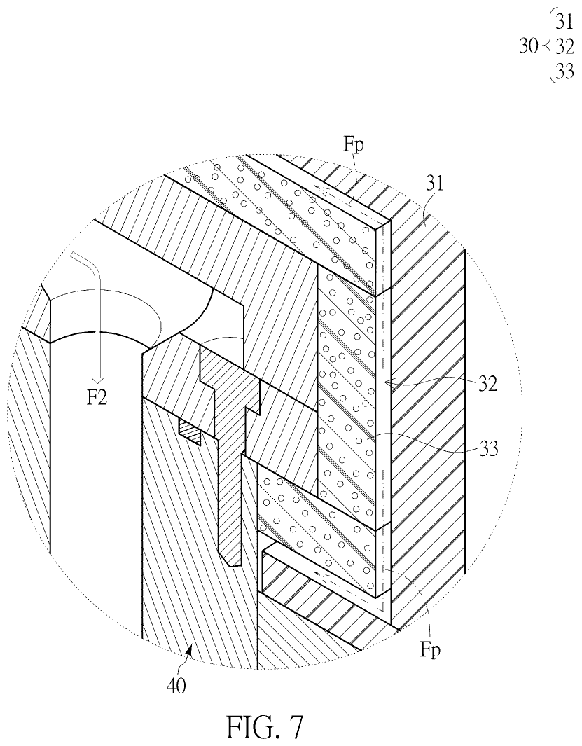

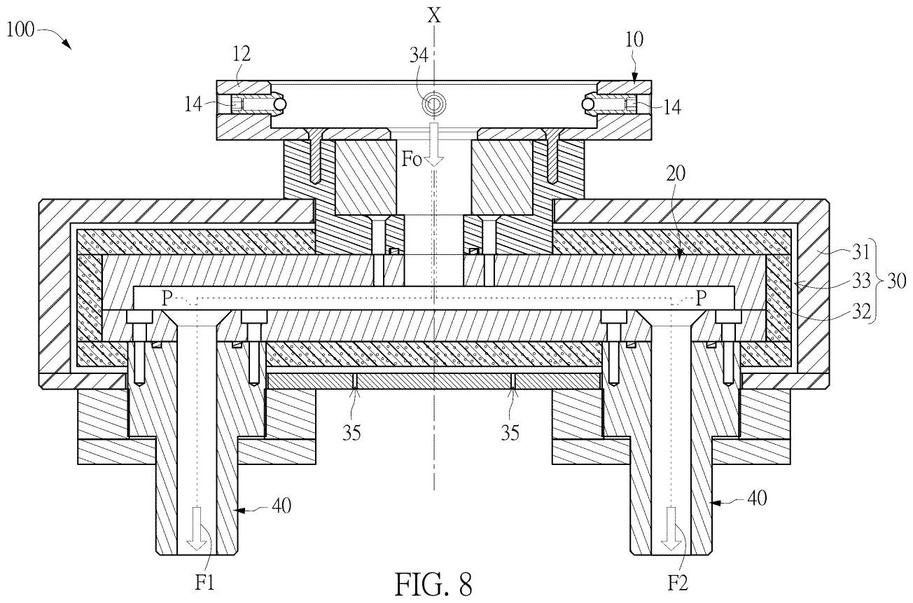

Referring to FIGS. 4 to 9, the manifold 100 is a kind of 1-to-2 adapter, that can effectively split the working fluid F0 of one flow into two fluid test flows F1, F2 respectively for the two testing caps 95. The manifold 100 includes a single thermal air inlet 10, a distributing mechanism 20 (as shown in FIG. 6 and FIG. 8), and a plurality of nozzles 40. The distributing mechanism 20 is fluidly communicated with the single thermal air inlet 10 to the plurality of nozzles 40, and is configured to distribute the working fluid F0 to at least two of the nozzles 40. The nozzles 40 have the same size. In this embodiment, two nozzles 40 are illustrated as an example. However, the present disclosure is not limited thereto. Various embodiments of multiple nozzles 40 are described below.

Referring to FIG. 8, a flow path P is defined in the manifold 100, and is substantially structurally symmetrical between the nozzles 40 along a central axis X of the single thermal air inlet 10. The thermal air inlet 10 is used to receive the working fluid F0 from an output end of the temperature control head 93. Each of the nozzles 40 has a flow path length along the flow path P that is substantially identical, and a cross-sectional area in the flow path P that is substantially identical, so that each of the two fluid test flows F1, F2 output from one of the nozzles 40 has a substantially uniform flow rate, a substantially uniform temperature, or both.

In this embodiment, the single thermal air inlet 10 includes a bushing cap interface 12 that is disposed on its top end. The bushing cap interface 12 includes a plurality of engaging members 14. The engaging members 14 are abutted against the temperature control head 93 of the temperature controlled test system 9. In a practical embodiment, the engaging member 14 can be a ball plunger, spring ball screw, or a wave bead positioning screw that has a ball and a spring to push the ball. Further, a manual screw S1 is provided to adjust the tightness between the bushing cap interface 12 and the temperature control head 93.

The distributing mechanism 20 is configured to ensure that the working fluid F0 exiting each of the nozzles 40 is substantially the same temperature by maintaining substantially equal flow path resistance across the nozzles 40. As used herein, “Flow path resistance,” refers to the resistance encountered by a fluid (e.g., air, gas, or liquid) as it travels through a defined conduit, duct, channel, or passage. This resistance may be a function of geometric parameters (e.g., length, cross-sectional area, curvature), surface characteristics (e.g., roughness), and/or internal components (e.g., valves, filters, or bends) located along the path. In one embodiment, the flow path resistance is determined using the Darcy-Weisbach equation, taking into account frictional losses in pipes that include bends and fittings. In another example, the resistance is adjusted by altering the cross-sectional area of the passage to regulate the fluid velocity. Flow path resistance may also be characterized based on fluid mechanics principles, such as pressure drop per unit length or flow coefficient values (e.g., Cv or Kv), without limitation to any specific computational model.

In a practical embodiment, the distributing mechanism 20 is a hollow, elongated, and flat capsule-shaped housing having a smooth inner surface, and has an upper opening 201 and at least two lower openings 202. The upper opening 201 is connected to the single thermal air inlet 10 for receiving the working fluid F0. The central axis X passes through a circle center of the upper opening 201. The two lower openings 202 are connected to the two nozzles 40, respectively. The shapes of the two lower openings 202 are the same. The locations of the two lower openings 202 are symmetrical along the central axis X.

Preferably, the manifold 100 further includes a thermal insulating housing 30. The thermal insulating housing 30 surrounds the flow path P that is configured to thermally insulate the distributing mechanism 20, so as to prevent the temperature of the flow path P from being affected by an external environment. Specifically, the thermal insulating housing 30 includes a purge channel 33 that is defined therein and at least partially surrounding the flow path P. The purge channel 33 is configured to direct a purge fluid (Fp) around the flow path P to prevent a formation of frost and condensation on the manifold.

The term “purge fluid” as used in the present disclosure refers to a fluid used to prevent the formation of frost and condensation on the manifold and associated components. The purge fluid is typically a gas or a liquid that is selected based on its thermal properties and ability to prevent moisture accumulation. Examples of the purge fluids include, but are not limited to, dry air, nitrogen gas, or any other inert gas that does not react with the materials of the manifold or the devices being tested. In certain embodiments, the purge fluid may also include a heated fluid or a dehumidified gas, depending on an operating environment and temperature conditions. The purge fluid (Fp) flows through the purge channel 33 surrounding the flow path P of the manifold 100, so as to effectively maintain temperature and humidity conditions within the thermal insulating housing 30 and avoid moisture-related issues (such as frost or condensation).

In a practical embodiment, the thermal insulating housing 30 includes an inner thermal insulation layer 32, and an outer shell 31. The inner thermal insulation layer 32 is attached to an outer surface of the distributing mechanism 20 to achieve thermal insulation and prevent leakage. The outer shell 31 is disposed outside the inner thermal insulation layer 32. The purge channel 33 is formed between the inner thermal insulation layer 32 and the outer shell 31. Preferably, the inner thermal insulation layer 32 is made of a thermal insulation material. For example, the inner thermal insulation layer 32 is made of silicone foam. The silicone foam is a silicone sheet made by adding a foaming agent into silicone rubber and preforming heating for generation of bubbles inside. The silicone foam is a versatile, lightweight, and flexible material used for sealing, insulation, and protection in various industries. A working temperature range of the silicone foam can withstand −20° C. to 200° C.

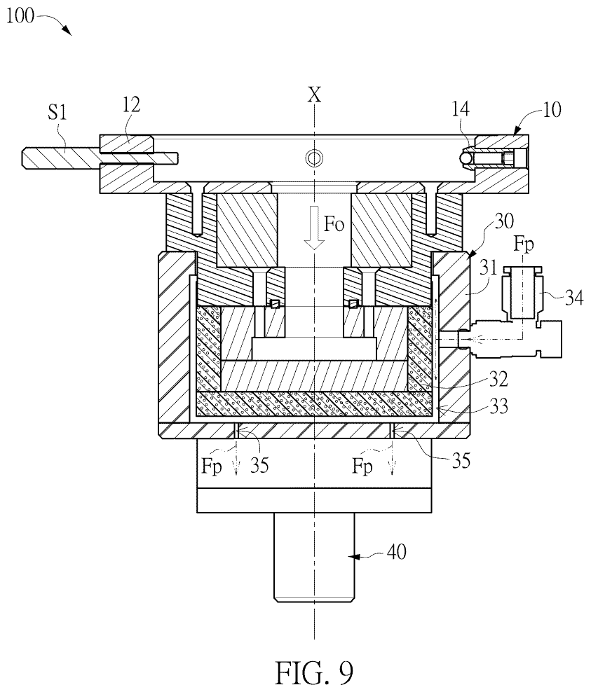

Referring to FIG. 4 and FIG. 9, the thermal insulating housing 30 further includes a purge inlet 34 to fluidly communicate with the purge channel 33, so that the purge fluid (Fp) can be supplied into the purge channel 33.

Referring to FIGS. 4 to 6, the thermal insulating housing 30 further includes a plurality of purge outlets 35 formed on an outer surface of the thermal insulating housing 30 and fluidly communicated with the purge channel 33. The purge outlets 35 are distributed around the outer surface of the thermal insulating housing 30 to direct the purge fluid (Fp) around and through the flow path P.

Each of the nozzles 40 includes a thermal insulating sleeve 42 disposed around its outer surface. The thermal insulating sleeve 42 is fixed to a bottom of the thermal insulating housing 30 and partially surrounds and/or covers the nozzle 40. The thermal insulating sleeve 42 is made of a thermal insulation material.

### Second Embodiment

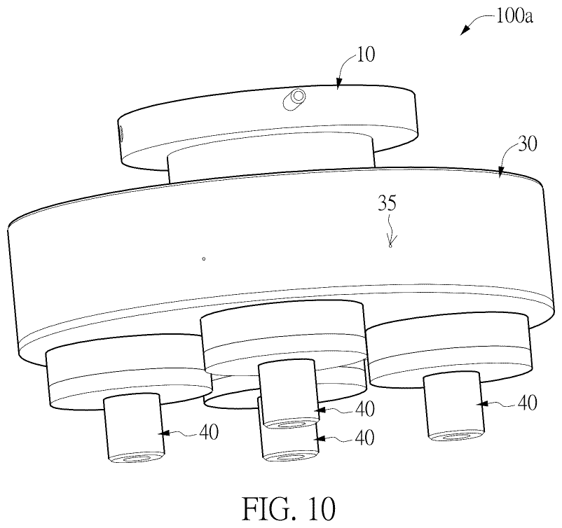

Referring to FIG. 10, a second embodiment of the present disclosure provides a manifold 100a, which includes a single thermal air inlet 10, a distributing mechanism (not shown) in a thermal insulating housing 30, and four nozzles 40. Similar to the distributing mechanism 20 in the first embodiment, the distributing mechanism in the present embodiment is fluidly communicated with the single thermal air inlet 10 to the plurality of nozzles 40, and is configured to distribute a working fluid to the plurality of nozzles 40. In this embodiment, the distributing mechanism can be a hollow, elongated, and flat circular housing having a smooth inner surface, and has an upper opening and four lower openings respectively for the four nozzles 40. However, the shape of the distributing mechanism is not limited thereto.

The input working fluid in this embodiment can be divided into four flow sub-paths, and the four flow sub-paths can be arranged in a cross shape. For example, the four flow sub-paths are separated by an angle of 90 degrees from each other. Each of the flow sub-paths has the same flow path length and the same cross-sectional area.

### Method of Distributing a Working Fluid

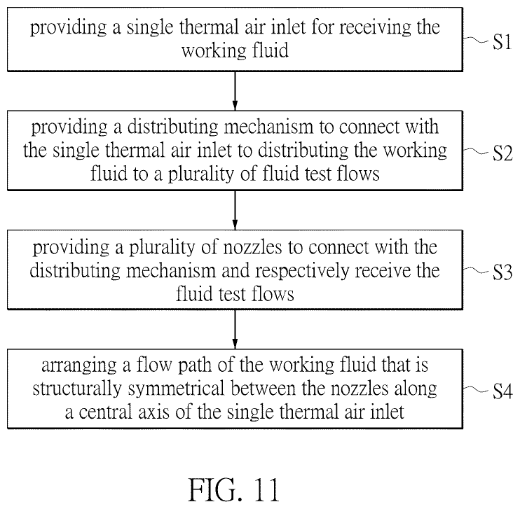

Reference is made FIG. 11, which is to be read in conjunction with FIGS. 1 to 9. Based on a temperature controlled test system 9, the present disclosure further provides a method of distributing a working fluid F0 from the temperature controlled test system 9 to a plurality of testing caps (or referred to as chambers) 95. The method includes the following steps.
Step S1: providing a single thermal air inlet 10 for receiving the working fluid F0.
Step S2: providing a distributing mechanism 20 to connect with the single thermal air inlet 10 for distributing the working fluid F0 to a plurality of fluid test flows (F1, F2).
Step S3: providing a plurality of nozzles 40 to connect with the distributing mechanism 20 and respectively receive the fluid test flows (F1, F2).
Step S4: arranging a flow path P of the working fluid F0 that is substantially structurally symmetrical between the nozzles 40 along a central axis X of the single thermal air inlet 10.

Each of the nozzles 40 has a flow path length along the flow path P that is substantially identical, and a cross-sectional area in the flow path P that is substantially identical so that the working fluid F0 output from each of the nozzles 40 has a substantially uniform flow rate, a substantially uniform temperature, or both.

In a practical embodiment, the method further includes a step of maintaining substantially equal flow path resistance across the nozzles 40 to ensure the working fluid exiting each of the nozzles 40 is substantially the same temperature.

In a practical embodiment, the method further includes a step of providing a thermal insulating housing 30 to at least partially surround the flow path P.

In a practical embodiment, the method further includes a step of forming a purge channel 33 in the thermal insulating housing 30 to at least partially surround the flow path P. The purge channel 33 is configured to direct a purge fluid (Fp) around the flow path P to prevent a formation of frost and condensation on a manifold.

In a practical embodiment, the method further includes a step of providing a purge inlet 34 formed on the thermal insulating housing 30 to fluidly communicate with the purge channel 33 to receive the purge fluid (Fp) into the purge channel 33.

In a practical embodiment, the method further includes a step of providing a plurality of purge outlets 35 formed on an outer surface of the thermal insulating housing 30 to fluidly communicate with the purge channel 33. The purge outlets 35 are distributed around the outer surface of the thermal insulating housing 30 to direct the purge fluid (Fp) around and through the flow path P.

### Method of Producing a Tested DUT

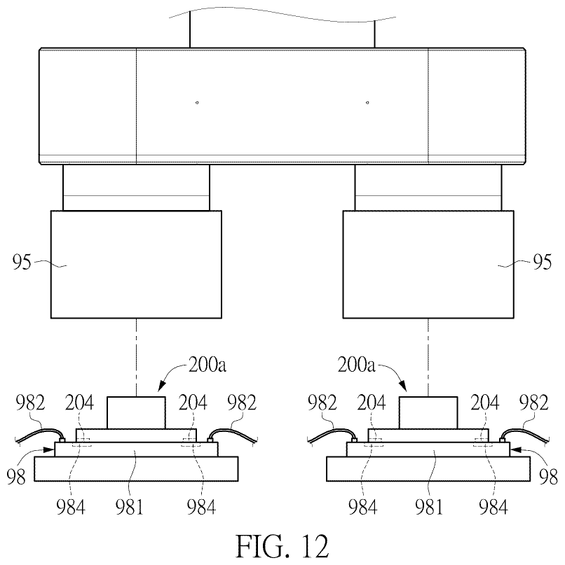

Reference is made to FIGS. 12, which is to be read in conjunction with FIGS. 1 to 9. Based on the temperature controlled test system 9, the present disclosure further provides a method of producing a tested device under test, such as a semiconductor device. The method includes the following steps.

Referring to FIG. 12, an device under test 200a is provided. The device under test 200a is one kind of electric DUTs. The DUT may include an unpackaged semiconductor device, such as a bare die formed on a wafer or substrate, or a packaged semiconductor device that has been encapsulated and provided with external electrical leads or contacts. The DUT can be, for example, a microprocessor, a memory, a mixed-signal IC, and a panel driver (such as a TFT (thin film transistor) or a PDP (plasma display panel) that drives liquid crystal).

A testing assembly 98 is connected with the device under test 200a by making the testing assembly 98 in contact with the contact 204 of the device under test 200a.

For example, the testing assembly 98 can be an electronic test apparatus, which includes a circuit substrate 981, and a plurality of connecting wires 982. The circuit substrate 981 has a plurality of contact pads 984 arranged in accordance with the arrangement of the contacts 204 (electrode portions) of the device under test 200a, and is electrically connected to the contacts 204 of the device under test 200a via the contact pads 984.

To test the device under test 200a by using the testing assembly 98 to transmit a signal between the device under test 200a and a tester through the connecting wires 982. However, the DUT can be connected with the tester in a wireless manner, such as Bluetooth, or WiFi. The tester, for example, can be as an external computer system for providing testing signals and monitoring the testing results. Specifically, the computer system could include a memory device, and a memory controller controlling the data processing operations of the memory device, a display and an input device. The DUT may display data through the display according to data input through the input device. The input device may be implemented by a computer mouse, or a keyboard.

To maintain uniform temperature and flow conditions during testing by utilizing the manifold 100 to distribute thermal air to the device under test 200a, ensuring consistent temperature control during testing.

In this embodiment, the distributing mechanism 20 of the manifold 100 can distribute the working fluid F0 to at least two nozzles 40. Therefore, at least two device under test 200a can be tested simultaneously by a testing process undergoing the temperature controlled test system 9 according to the above embodiments. After the testing process is completed and qualified, the device under test 200a becomes a tested semiconductor device.

The temperature controlled test system 9 includes the manifold 100 that is configured to ensure uniform temperature and flow conditions for the semiconductor device during the testing process.

However, the aforementioned details are disclosed for exemplary purposes only, and are not meant to limit the scope of the present disclosure.

### Beneficial Effects of the Embodiments

In conclusion, the manifold of the temperature controlled test system for conditioning the device-under-test (DUT) provided by the present disclosure, offers significant improvements in testing efficiency and cost-effectiveness. The system employs a distributing mechanism fluidly connected to a single thermal air inlet and configured to deliver conditioned working fluid to a plurality of nozzles, thereby enabling simultaneous thermal conditioning of multiple DUTs under uniform temperature and flow conditions. This parallel testing capability eliminates the need for sequential testing or multiple isolated thermal chambers, thereby reducing overall testing time and setup costs. Furthermore, because each DUT is conditioned individually through its own dedicated nozzle and flow path-rather than sharing a common thermal chamber-the risk of mutual interference among DUTs (e.g., electromagnetic crosstalk or airflow obstruction) is significantly reduce. As a result, the disclosed system improves testing accuracy and repeatability, while also streamlining the infrastructure required for environmental control during testing. The structurally symmetrical manifold design ensures consistent thermal delivery to each DUT, rendering the system particularly suitable for high-throughput and precision testing environments.

As used herein, “substantially identical,” when referring to physical parameters such as length, cross-sectional area, or flow path resistance, includes values that are not necessarily mathematically identical but are sufficiently close to produce functionally equivalent results in the context of fluid distribution and thermal performance. For example, each of the nozzles may have a flow path length along the flow path that varies by no more than ±2%, and a cross-sectional area in the flow path that also varies by no more than ±2%. In practice, the actual dimensional variation of the disclosed product is approximately 0.2%, which ensures that flow characteristics across all nozzles remain within acceptable tolerance to maintain uniform fluid delivery.

As used herein, “substantially uniform,” when referring to output flow rate or temperature of the working fluid, encompasses variations that do not materially affect the effectiveness of thermal conditioning or testing consistency across multiple DUTs. A flow rate or temperature is considered substantially uniform when deviations among nozzles remain within an acceptable performance range. In one practical embodiment, the flow rate variation is controlled to be less than 1%, and the temperature variation is maintained within ±0.15° C. across all nozzles. These tolerances ensure that each DUT receives nearly identical thermal exposure, thereby promoting high repeatability and reliability in test conditions. Accordingly, “substantially uniform” conditions refer to output values that fall within these defined tolerances and support accurate, consistent, and reproducible testing environments.

As used herein, the term “device under test” or “DUT” broadly refers to any physical item subjected to testing within a temperature-controlled or electrically controlled environment. The DUT may include, but is not limited to: Semiconductor devices (e.g., integrated circuits, dies, wafers); Electronic components (e.g., resistors, capacitors, transistors, IC packages); Materials used in electronic applications (e.g., substrates, interposers, thermal interface materials); Printed circuit boards (PCBs) or modules; Any component or assembly being evaluated for performance, reliability, or thermal characteristics. The terms “tested device,” “test object,” “tested semiconductor device,” or variations thereof, as used throughout this disclosure, are to be interpreted synonymously with “device under test” (DUT), unless expressly stated otherwise.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manifold of a temperature controlled test system for conditioning a device-under-test, comprising:
a single thermal air inlet for receiving a working fluid;
a plurality of nozzles;
a distributing mechanism fluidly communicated with the single thermal air inlet to the plurality of nozzles, and configured to distribute the working fluid to at least two of the plurality of nozzles; and
a flow path defined in the manifold, wherein the flow path is substantially structurally symmetrical between the plurality of nozzles along a central axis of the single thermal air inlet;
wherein each of the plurality of nozzles has a flow path length along the flow path that is substantially identical, and has a cross-sectional area in the flow path that is substantially identical; so that the working fluid output from each of the nozzles has a substantially uniform flow rate, a substantially uniform temperature, or both.

2. The manifold according to claim 1, wherein the distributing mechanism is configured to ensure that the working fluid exiting each of the nozzles has substantially a same temperature by maintaining a substantially equal flow path resistance across the nozzles.

3. The manifold according to claim 1, further comprising a thermal insulating housing, wherein the thermal insulating housing surrounds the flow path.

4. The manifold according to claim 3, wherein the thermal insulating housing includes a purge channel that is defined therein and at least partially surrounds the flow path; wherein the purge channel is configured to direct a purge fluid around the flow path to prevent formation of frost and condensation on the manifold.

5. The manifold according to claim 4, wherein the thermal insulating housing further includes a purge inlet to fluidly communicate with the purge channel, so as to receive the purge fluid into the purge channel.

6. The manifold according to claim 4, wherein the thermal insulating housing further includes a plurality of purge outlets formed on an outer surface of the thermal insulating housing and fluidly communicated with the purge channel, and the plurality of purge outlets are distributed around the outer surface of the thermal insulating housing to direct the purge fluid around and through the flow path.

7. The manifold according to claim 4, wherein the thermal insulating housing further includes an inner thermal insulation layer, and an outer shell, the inner thermal insulation layer is attached to the distributing mechanism, the outer shell is disposed outside of the inner thermal insulation layer, and the purge channel is formed between the inner thermal insulation layer and the outer shell.

8. The manifold according to claim 7, wherein the inner thermal insulation layer is made of silicone foam.

9. The manifold according to claim 1, wherein the single thermal air inlet further includes a bushing cap interface disposed on a top end thereof, the bushing cap interface includes a plurality of engaging members, and the engaging members are abutted against a temperature control head of the temperature controlled test system.

10. The manifold according to claim 1, wherein each of the nozzles includes a thermal insulating sleeve disposed around thereof.

11. A temperature controlled test system comprising:
a working fluid supply machine for supplying a working fluid;
an output tube connected to the working fluid supply machine for receiving the working fluid;
a temperature control head connected to the output tube;
the manifold as claimed in claim 1, wherein the single thermal air inlet of the manifold is connected to the temperature control head; and
a plurality of testing caps respectively connected to the plurality of nozzles.

12. A method of distributing a working fluid from a temperature controlled test system to a plurality of testing caps, comprising processes of:
providing a single thermal air inlet for receiving the working fluid;
providing a distributing mechanism to connect with the single thermal air inlet to distributing the working fluid to a plurality of fluid test flows;
providing a plurality of nozzles to connect with the distributing mechanism and respectively receive the fluid test flows; and
arranging a flow path of the working fluid that is substantially structurally symmetrical between the nozzles along a central axis of the single thermal air inlet;
wherein each of the nozzles has a flow path length along the flow path that is substantially identical, and has a cross-sectional area in the flow path that is substantially identical so that the working fluid output from each of the nozzles has a substantially uniform flow rate, a substantially uniform temperature, or both.

13. The method according to claim 12, further comprising a process of: maintaining a substantially equal flow path resistance across the nozzles to ensure the working fluid exiting each of the nozzles has substantially a same temperature.

14. The method according to claim 12, further comprising a process of: providing a thermal insulating housing to at least partially surround the flow path.

15. The method according to claim 14, further comprising a process of: forming a purge channel in the thermal insulating housing to at least partially surround the flow path; wherein the purge channel is configured to direct a purge fluid around the flow path to prevent formation of frost and condensation on the manifold.

16. The method according to claim 15, further comprising a process of: disposing a purge inlet on the thermal insulating housing to fluidly communicate with the purge channel, so as to receive the purge fluid into the purge channel.

17. The method according to claim 16, further comprising a process of: disposing a plurality of purge outlets on an outer surface of the thermal insulating housing to fluidly communicate with the purge channel, wherein the plurality of purge outlets are distributed around the outer surface of the thermal insulating housing to direct the purge fluid around and through the flow path.

18. A method of producing a tested device under test (DUT), comprising:
providing the temperature controlled test system as claimed in claim 11;
providing an DUT;
electrically connecting a testing assembly with the DUT; and
testing the DUT by using the testing assembly to transmit a signal between the DUT and a tester; and
maintaining uniform temperature and flow conditions during testing by utilizing the manifold to distribute thermal air to the DUT, ensuring consistent temperature control during the test.

19. A tested device under test (DUT), comprising:
at least two DUTs being tested simultaneously by a testing process, the testing process being performed by using the temperature controlled test system as claimed in claim 11,
wherein the temperature controlled test system includes the manifold that is configured to ensure uniform temperature and flow conditions for the DUTs during testing.
